(19) United States
(12) Patent Application Publication
(10) Pub. No.: US 2011/0272773 A1
(43) Pub. Date: Nov. 10, 2011

(54) METHOD FOR MANUFACTURING SOLID-STATE IMAGE SENSING DEVICE, AND SOLID-STATE IMAGE SENSING DEVICE

(75) Inventor: Yoichi Kazama, Nagano-shi (JP)

(73) Assignee: Shinko Electric Industries Co., Ltd., Nagano-shi (JP)

(21) Appl. No.: 13/097,457

(22) Filed: Apr. 29, 2011

(30) Foreign Application Priority Data
May 6, 2010 (JP) 2010-106701

(51) Int. Cl. H01L 31/0203

(52) U.S. Cl. 257/433; 257/E31.117

(57) ABSTRACT

A method for manufacturing a solid-state image sensing device, includes mounting a solid-state image sensor on a substrate, forming an elastic layer on a first surface of a glass lid, fixing the glass lid onto the solid-state image sensor with a bonding agent so that the glass lid covers the solid-state image sensor while a second surface opposite to the first surface of the glass lid faces the solid-state image sensor, electrically connecting a terminal provided on the solid-state image sensor, to a terminal provided on the substrate, through a wire, and encapsulating the wire and covering a side surface of the glass lid with a resin.

### TECHNICAL FIELD

The present disclosure relates to a method for manufacturing a solid-state image sensing device for use in a digital camera or the like, and the solid-state image sensing device.

### RELATED ART

There are solid-state image sensing devices mounted with solid-state image sensors such as CCD image sensors or CMOS image sensors.

Typically in such a solid-state image sensing device 10, as shown in FIGS. 9 and 10, a solid-state image sensor 14 is mounted on a substrate 12 and covered with a glass lid 16. The glass lid 16 is fixed onto the solid-state image sensor 14 with a bonding agent 18. Terminals provided in a circumferential edge portion of the solid-state image sensor 14 are electrically connected through wires 20 to terminals provided in a circumferential edge portion of the substrate 12. The wires 20 are encapsulated with a sealing resin 22 (Patent Document 1). Solder bumps (not shown) or the like serving as external connection terminals are provided on a lower side of the substrate 12.

### PRIOR TECHNICAL DOCUMENT

### Patent Document

[Patent Document 1] JP-A-2007-141957

The sealing resin 22 in the solid-state image sensing device 10 is formed by potting or by resin molding with a mold.

Although the sealing resin 22 is provided for encapsulating the wires 20 or covering a side surface of the glass lid 16, it is however impossible to avoid occurrence of a so-called bleed phenomenon in which the sealing resin 22 climbs up onto a circumferential edge portion of a front surface of the glass lid 16 when the sealing resin 22 is formed by potting.

On the other hand, when the sealing resin is formed by resin molding with a mold, extremely high accuracy is required in the height of an assembly 26 to be installed in the mold. The assembly 26 is made of the substrate 12, the solid-state image sensor 14 and the glass lid 16. That is, when the height of the assembly 26 is lower than a set height, a gap appears between a surface of a cavity formed in the mold and the front surface of the glass lid 16. Thus, it is impossible to avoid a so-called flash phenomenon in which the sealing resin 22 flows onto the front surface of the glass lid 16 to form a resin burr 24 thereon (FIG. 11). On the contrary, when the height of the assembly 26 is higher than the set height, the glass lid 16 abuts against an inner wall surface of the cavity. Thus, there is a problem that the glass lid 16 is cracked due to pressure applied thereto from the inner wall surface of the cavity. The total height of the assembly 26 is about 1.1 to 1.2 mm. Therefore, it is impossible to avoid occurrence of any one of the problems due to a variation in the total height of the assembly 26 caused by dimensional variations among the substrate 12, the solid-state image sensor 14 and the glass lid 16.

### SUMMARY

Exemplary embodiments of the present invention provide a method for manufacturing a solid-state image sensing device and the solid-state image sensing device, which can effectively prevent a sealing resin from producing a bleed phenomenon or a flash phenomenon on a front surface of a glass lid, and also can prevent the glass lid from being cracked.

A method for manufacturing a solid-state image sensing device, according to an exemplary embodiment of the invention comprises:

mounting a solid-state image sensor on a substrate;

forming an elastic layer on a first surface of a glass lid;

fixing the glass lid onto the solid-state image sensor with a bonding agent so that the glass lid covers the solid-state image sensor while a second surface opposite to the first surface of the glass lid faces the solid-state image sensor;

electrically connecting a terminal provided on the solid-state image sensor, to a terminal provided on the substrate, through a wire; and

encapsulating the wire and covering a side surface of the glass lid with a resin.

The forming the elastic layer on the glass lid may include forming a frame-like elastic layer on a circumferential edge portion of the first surface of the glass lid.

The forming the frame-like elastic layer on the glass lid may include forming a plurality of frame-like elastic layers on a glass plate with a gap between adjacent ones of the frame-like elastic layers, and cutting the glass plate along the gap and separating the glass plate into individual glass lids.

The cutting the glass plate may include cutting the glass plate along the gap so that a step portion which is not covered with the frame-like elastic layer is formed in an outermost circumferential edge portion of the first surface of the glass lid, and in the encapsulating and covering with the resin, the step portion may be covered with the resin.

The elastic layer may be formed by applying a light curable resin onto a glass plate, and exposing the light curable resin to light and developing it.

The encapsulating and covering with the resin may include performing a resin molding using a mold. Alternatively, the encapsulating and covering with the resin may include potting the resin.

A solid-state image sensing device according to an exemplary embodiment of the invention comprises:

a substrate;

a solid-state image sensor which is mounted on the substrate;

a glass lid which is fixed onto the solid-state image sensor with a bonding agent so that the glass lid covers the solid-state image sensor while a lower surface of the glass lid faces the solid-state image sensor;

a wire which electrically connects a terminal provided in a circumferential edge portion of the solid-state image sensor with a terminal provided in a circumferential edge portion of the substrate; and

a resin which encapsulates the wire, and covers a side surface of the glass lid and a circumferential edge portion of an upper surface of the glass lid.

The solid-state image sensing device may further comprise:

a frame-like elastic layer formed inside the resin on the circumferential edge portion of the upper surface of the glass lid.

According to the exemplary embodiments, it is possible to effectively prevent a sealing resin from producing a bleed phenomenon or a flash phenomenon on a front surface of a glass lid, and it is also possible to prevent the glass lid from being cracked.

### BRIEF DESCRIPTION OF THE DRAWINGS

FIG. 1 is a view showing a state where frame-like elastic layers are formed on a large-sized glass plate.

FIG. 2 is a view showing a state where the large-sized glass plate is cut into individual glass lids.

FIG. 3 is a plan view showing an individual glass lid.

FIG. 4 is a front view showing the individual glass lid.

FIG. 5 is a sectional view showing an assembly.

FIG. 6 is a view showing a state where the assembly is disposed in a molding mold.

FIG. 7 is a sectional view showing a solid-state image sensing device.

FIG. 8 is a plan view showing the solid-state image sensing device.

FIG. 9 is a view showing an assembly in a solid-state image sensing device according to a related art.

FIG. 10 is a sectional view showing an example of the solid-state image sensing device according to the related art.

FIG. 11 is a view showing an example in which a flash phenomenon of a resin burr has occurred on a glass lid.

### DETAILED DESCRIPTION

An exemplary embodiment of the invention will be described below in detail with reference to the accompanying drawings.

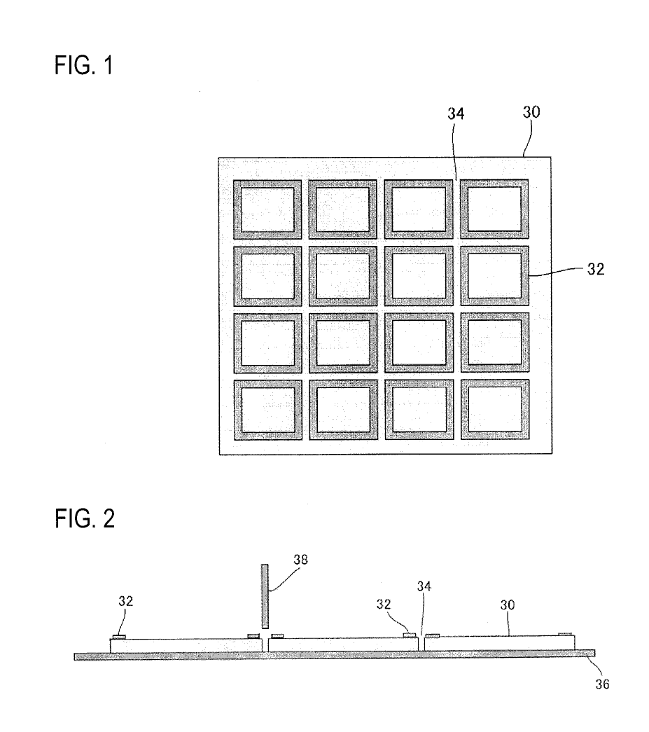

FIGS. 1 to 4 are views for explaining steps of manufacturing a glass lid 16.

First, as shown in FIG. 1, a glass plate 30 is prepared. The glass plate 30 has a size large enough to form a plurality (sixteen in the example of FIG. 1) of glass lids 16. Each glass lid 16 to be manufactured is about 6 to 7 mm square. A thickness of each glass lid 16 to be manufactured is about 0.4 mm.

A light curable resin such as an ultraviolet curable epoxy resin is applied on the whole surface of the glass plate 30, and exposed to light through a desired mask (not shown). Then, the light curable resin is developed so that frame-like elastic layers 32 are formed in circumferential edge portions of regions which will serve as individual glass lids 16 (photolithography step). A resin which has desired elasticity and heat resistance is used as the light curable resin.

When the frame-like elastic layers 32 are produced, a gap 34 of a desired distance (for example, about 0.4 mm) may be formed between adjacent ones of the frame-like elastic layers 32.

Each frame-like elastic layer 32 is formed to be about 0.10 to 0.15 mm thick and about 0.3 to 0.5 mm wide.

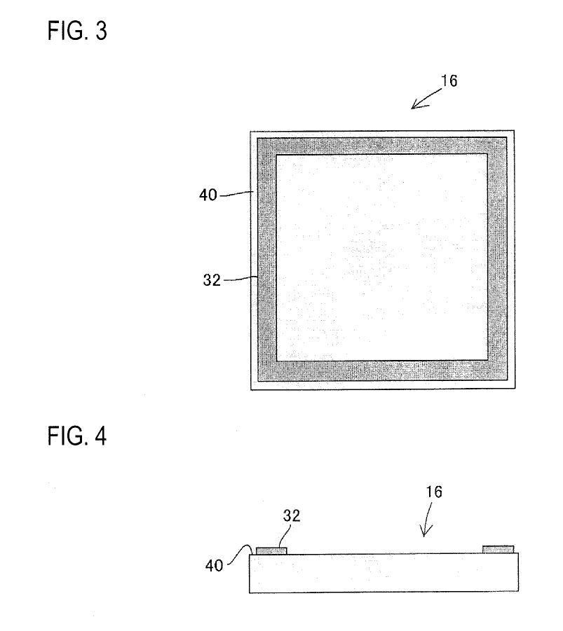

A dicing tape 36 is pasted to a rear surface side of the glass plate 30 opposite to the front surface where the frame-like elastic layers 32 have been formed. The glass plate 30 is cut along the gap 34 by a dice 38 (FIG. 2) and separated into individual glass lids 16 (FIGS. 3 and 4).

When the width of the gap 34 between adjacent ones of the frame-like elastic layers 32 is made larger than the width of cutting with the dice 38, a step portion 40 which is not covered with any frame-like elastic layer 32 can be formed in the outermost circumferential edge portion of each glass lid 16. The step portion 40 has, for example, about 0.1 mm wide.

Provision of the gap 34 may not be necessary. An elastic layer having a plurality of openings corresponding to the regions which will serve as individual glass lids 16 and the glass plate 30 may be cut simultaneously by the dice 38 and separated into individual frame-like elastic layers 32 and glass lids 16. However, when the elastic layer and the glass plate which are made of different materials respectively are cut by the dice 38 at the same time, there is a fear that a cutting burr may be produced in the elastic layer or a very small crack may be produced in an edge portion of the glass lid according to the cutting conditions. It is therefore preferable that a gap 34 with a desired width is provided between adjacent ones of the frame-like elastic layers 32 so that only the glass plate can be cut. In addition, when the step portion 40 is formed, there is another merit that a sealing resin can be put on the step portion 40 so as to produce an anchor effect, as will be described later.

In the embodiment, a light curable resin is applied on the whole surface of the glass plate 30 so that the frame-like elastic layers 32 are formed by the photolithography step. However, a light curable resin film may be bonded and fixed to the glass plate 30, for example, by thermal compression bonding.

Alternatively, frame-like elastic layers 32 may be formed in such a manner that the frame-like elastic layers 32 formed into frame-like shapes in advance are bonded to the glass plate 30 by thermal compression bonding.

In addition, thickness, width, etc. of each frame-like elastic layer 32 are not limited to the aforementioned numeric values.

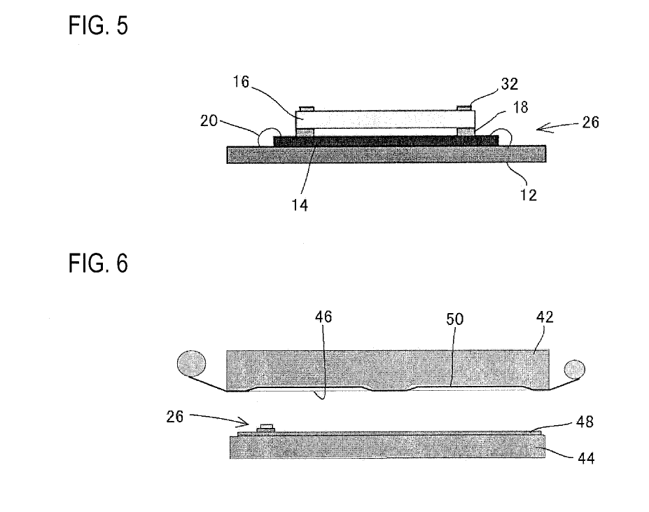

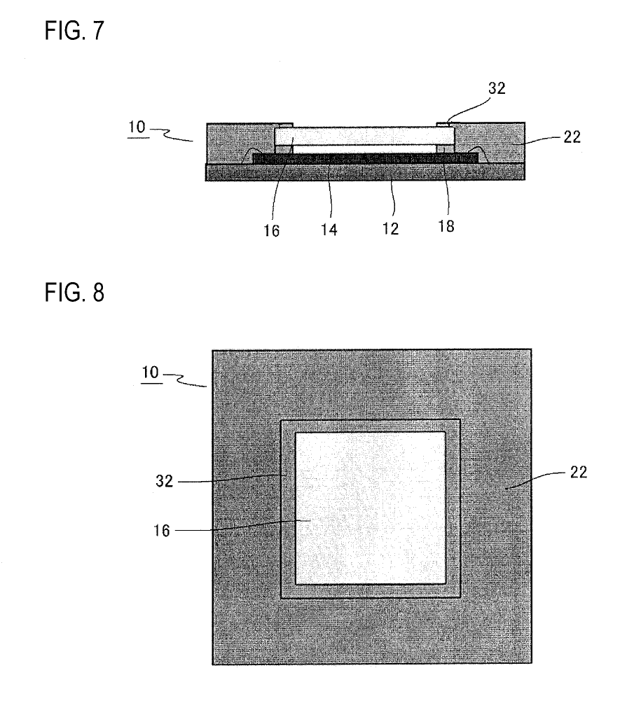

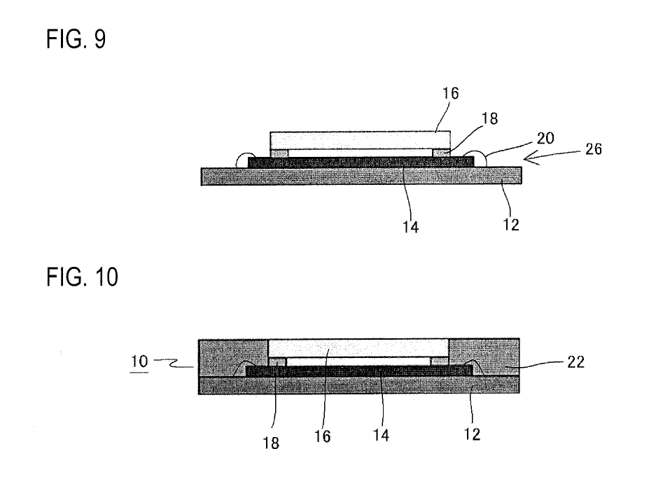

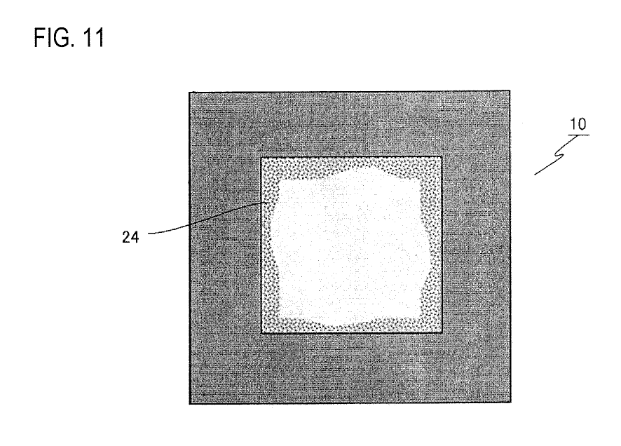

Next, description will be made on a method for manufacturing the solid-state image sensing device 10 using the glass lid 16. As shown in FIG. 5, a solid-state image sensor 14 is fixed onto a substrate 12 with a suitable bonding agent. The substrate 12 has a size larger than the solid-state image sensor 14. In the substrate 12, terminals (not shown) are formed in a portion exposed outside the solid-state image sensor 14.

Then, the glass lid 16 including the frame-like elastic layer 32 is fixed onto the solid-state image sensor 14 with an ultraviolet curable bonding agent 18 so that the solid-state image sensor 14 is covered with the glass lid 16 while the frame-like elastic layer 32 faces outside (upward) (in other words, a lower surface of the glass lid 16, which is opposite to an upper surface where the frame-like elastic layer 32 is formed, faces the solid-state image sensor 14). A desired space is formed between the solid-state image sensor 14 and the glass lid 16 with the bonding agent 18 serving as a spacer.

The solid-state image sensor 14 has a size larger than the glass lid 16. In the solid-state image sensor 14, terminals (not shown) are formed in a portion exposed outside the glass lid 16.

Then, the terminals of the solid-state image sensor 14 and the terminals of the substrate 12 are electrically connected through wires 20. Thus, an assembly 26 is formed.

As shown in FIG. 6, the assembly 26 is disposed between upper and lower molds 42 and 44 of a transfer molding machine (not shown).

Only one assembly is shown as the assembly 26 in FIG. 5. However, a substrate sheet 48 in which a plurality of substrates are built up in a form of a matrix is used in fact. Assemblies 26 in each of which the solid-state image sensor 14 and the glass lid 16 are installed on each of the substrates 12 of the substrate sheet 48 are used. The assemblies 26 are disposed between the upper and lower molds 42 and 44. For the sake of simplification of the drawing, not all the assemblies but only one assembly 26 is shown in FIG. 6. A desired cavity 46 for encapsulating the wires 20 with a resin is formed in the upper and lower molds 42 and 44.

Then, the upper and lower molds 42 and 44 are closed.

When the molds are closed, an inner wall surface of the cavity 46 abuts against the frame-like elastic layer 32 because the frame-like elastic layer 32 with a desired thickness has been formed on a front surface of the glass lid 16. Thus, the molds are closed with pressure applied to the frame-like elastic layer 32.

In manufacturing, some variation inevitably appears in each thickness of the substrate 12, the solid-state image sensor 14, the bonding agent 18 and the glass lid 16. The thickness of the frame-like elastic layer 32 is set to absorb such a variation of thickness on the assembly 26 side.

Then, a sealing resin which is melted is injected into the cavity so that the wires 20 are encapsulated with the resin.

As described above, the inner wall surface of the cavity 46 and the frame-like elastic layer 32 are brought into tight contact without any gap when the molds are closed. Thus, when the melted sealing resin is injected into the cavity, the melted sealing resin does not enter the gap so that the flash phenomenon (resin burr) can be effectively prevented from occurring. In addition, the inner wall surface of the cavity comes into gentle contact with the glass lid 16 through the frame-like elastic layer 32. Thus, there is no such problem as in the related art that the inner wall surface of the cavity comes into direct contact with the glass lid 16 to crack the glass lid 16 when the height of the assembly 26 is higher than a set height.

Whether the height of the assembly 26 is lower or higher than the set height, the frame-like elastic layer 32 can absorb the variation of the height.

After the resin molding, the molds are opened and the assemblies 26 are extracted from the molds. External connection terminals (not shown) such as solder bumps are attached onto the predetermined terminals of each assembly on a lower side of the substrate sheet 48. The substrate sheet 48 is cut and separated into individual substrates 12. Thus, individual solid-state image sensing devices 10 are completed.

Incidentally, the reference numeral 50 represents a release film which makes it possible to separate molded pieces from the molds easily. The release film 50 does not have to be always used.

The sealing resin 22 is formed by resin molding with a mold in the embodiment. However, in the case where the sealing resin 22 is formed by potting, the frame-like elastic layer 32 serves as a dam to prevent the potting resin from climbing up onto the front surface of the glass lid 16. Thus, the bleed phenomenon can be effectively prevented from occurring.

When the step portion 40 is produced in the outermost circumferential edge of the glass lid 16 as described above, the step portion 40 is filled with a molding resin or a potting resin so as to press the edge portion of the glass lid 16 from above. Thus, the anchor effect of the glass lid 16 occurs. In addition, the edge portion of the glass lid 16 is perfectly covered by the resin. Therefore, even if a very small crack appears in the edge portion, such a problem that a very small chip adheres to the front surface of the glass lid 16 can be solved.

Incidentally, the concept of the glass lid 16 may include not only so-called glass but also a wide variety of transparent members.

In addition, the frame-like elastic layer 32 may be left on the glass lid 16 as it is, or may be removed from the glass lid 16.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method for manufacturing a solid-state image sensing device, comprising:
mounting a solid-state image sensor on a substrate;
forming an elastic layer on a first surface of a glass lid;
fixing the glass lid onto the solid-state image sensor with a bonding agent so that the glass lid covers the solid-state image sensor while a second surface opposite to the first surface of the glass lid faces the solid-state image sensor;
electrically connecting a terminal provided on the solid-state image sensor, to a terminal provided on the substrate, through a wire; and
encapsulating the wire and covering a side surface of the glass lid with a resin.

2. The method for manufacturing a solid-state image sensing device according to claim 1, wherein
the forming the elastic layer on the glass lid includes forming a frame-like elastic layer on a circumferential edge portion of the first surface of the glass lid.

3. The method for manufacturing a solid-state image sensing device according to claim 2, wherein
the forming the frame-like elastic layer on the glass lid includes forming a plurality of frame-like elastic layers on a glass plate with a gap between adjacent ones of the frame-like elastic layers, and cutting the glass plate along the gap and separating the glass plate into individual glass lids.

4. The method for manufacturing a solid-state image sensing device according to claim 3, wherein
the cutting the glass plate includes cutting the glass plate along the gap so that a step portion which is not covered with the frame-like elastic layer is formed in an outermost circumferential edge portion of the first surface of the glass lid, and
in the encapsulating and covering with the resin, the step portion is covered with the resin.

5. The method for manufacturing a solid-state image sensing device according to claim 1, wherein
the forming the elastic layer on the glass lid includes applying a light curable resin onto a glass plate, and exposing the light curable resin to light and developing it.

6. The method for manufacturing a solid-state image sensing device according to claim 1, wherein
the encapsulating and covering with the resin includes performing a resin molding using a mold.

7. The method for manufacturing a solid-state image sensing device according to claim 1, wherein
the encapsulating and covering with the resin includes potting the resin.

8. A solid-state image sensing device comprising:
a substrate;
a solid-state image sensor which is mounted on the substrate;
a glass lid which is fixed onto the solid-state image sensor with a bonding agent so that the glass lid covers the solid-state image sensor while a lower surface of the glass lid faces the solid-state image sensor;
a wire which electrically connects a terminal provided in a circumferential edge portion of the solid-state image sensor with a terminal provided in a circumferential edge portion of the substrate; and
a resin which encapsulates the wire, and covers a side surface of the glass lid and a circumferential edge portion of an upper surface of the glass lid.

9. The solid-state image sensing device according to claim 8, further comprising:
a frame-like elastic layer formed inside the resin on the circumferential edge portion of the upper surface of the glass lid.
